(19) United States
(12) Patent Application Publication
(10) Pub. No.: US 2009/0224353 A1
(43) Pub. Date: Sep. 10, 2009

(54) Diode

(75) Inventors: Takeo Yamamoto, Nishikamo-gun (JP); Takeshi Endo, Obu-city (JP); Yukihiko Watanabe, Nagoya-shi (JP); Takashi Katsuno, Ichinomiya-shi (JP); Masayasu Ishiko, Nagoya-shi (JP); Hirokazu Fujiwara, Nishikamo-gun (JP); Masaki Konishi, Toyota-shi (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 12/382,012

(22) Filed: Mar. 5, 2009

(30) Foreign Application Priority Data
Mar. 6, 2008 (JP) 2008-57024

(51) Int. Cl. H01L 29/872

(52) U.S. Cl. 257/471; 257/E29.338

(57) ABSTRACT

A diode includes the following: an n type semiconductor region; a p type semiconductor region provided in a part of a front face of the n type semiconductor region; an anode electrode (front face electrode) which adjoins a front face of the n type semiconductor region and a front face of the p type semiconductor region while at least forming a Schottky junction on a front face of the n type semiconductor region; and an insulating region which has a right-hand side (first side) and a left-hand side (second side) adjacent to the n type semiconductor region, the right-hand side facing a second n type semiconductor region which is located below the Schottky junction, the left-hand side facing a first n type semiconductor region which is located below a pn junction between the n type semiconductor region and the p type semiconductor region.

### CROSS REFERENCE TO RELATED APPLICATION

This application is based on and incorporates herein by reference Japanese Patent Application No. 2008-57024 filed on Mar. 6, 2008.

### FIELD OF THE INVENTION

The present invention relates to a diode provided with a Schottky junction.

### BACKGROUND OF THE INVENTION

Patent Document 1: JP-H10-321879A

There is known a diode having an n type semiconductor region and a p type semiconductor region in a surface layer portion of a semiconductor layer. An anode electrode of such a diode forms a Schottky junction with both of the n type semiconductor region and the p type semiconductor region. This kind of the diode is called a JBS (Junction Barrier Schottky) type diode. An example of the JBS type diode is disclosed by Patent document 1.

A general configuration of the JBS type diode 100 is illustrated in FIG. 23. The diode 100 is provided with a cathode electrode 104, a semiconductor substrate 103, and an anode electrode 102. The semiconductor substrate 103 contains an n⁺ type cathode region 110, an n type semiconductor region 112, and several p type semiconductor regions 114. The p type semiconductor regions 114 are arranged so as to be dispersed on a front face of the n type semiconductor region. The anode electrode 102 forms a Schottky junction with both the n type semiconductor region 112 and the p type semiconductor region 114.

When the anode electrode 102 is supplied with a voltage higher than the cathode electrode 104 (i.e., when a forward voltage is applied), the electric current flows from the anode electrode 102 through the Schottky junction Jb, the n type semiconductor region 112, and the cathode region 110 then into the cathode electrode 104. When the cathode electrode 104 is supplied with a voltage higher than the anode electrode 102 (i.e., when a reverse voltage is applied), a depletion layer spreads from a junction plane of the pn junction 113 between the p type semiconductor region 114 and the n type semiconductor region 112. When several p type semiconductor regions 114 are arranged to be dispersed on the front face of the n type semiconductor region 112, the depletion layer spreads widely, thereby providing a high withstand voltage. The JBS type diode 100 can thus raise the withstand voltage rather than the conventional Schottky diode which does not contain a p type semiconductor region 114.

In contrast, although the JBS type diode 100 has the pn junction formed by the p type semiconductor region 114 and the n type semiconductor region 112, it seems that the pn junction does not function substantially as a diode.

### SUMMARY OF THE INVENTION

It is an object of the present invention to provide, in a diode having a p type semiconductor region in a part of a front face of an n type semiconductor region, a technology which utilizes an internal pn junction diode and reduces a forward resistance.

According to an example of the present invention, a diode is provided as follows. An n type semiconductor region is included. A p type semiconductor region is provided in a part of a front face of the n type semiconductor region. An anode electrode is included to adjoin a front face of the n type semiconductor region and a front face of the p type semiconductor region while at least forming a Schottky junction on a front face of the n type semiconductor region. An insulating region is included to have a first side and a second side adjacent to the n type semiconductor region. Herein, the first side facing the second n type semiconductor region which is located below the Schottky junction, while the second side facing the n type semiconductor region which is located below a pn junction between the n type semiconductor region and the p type semiconductor region.

### BRIEF DESCRIPTION OF THE DRAWINGS

The above and other objects, features, and advantages of the present invention will become more apparent from the following detailed description made with reference to the accompanying drawings. In the drawings:

FIG. 1 is a diagram of a sectional view illustrating a diode according to a first embodiment of the present invention;

FIG. 2 is a diagram of a top view illustrating a semiconductor substrate of the diode according to the first embodiment;

FIG. 3 is a diagram illustrating a voltage and current density characteristic of the diode according to the first embodiment;

FIG. 4 is a diagram for illustrating a route of an electric current flowing via a Schottky junction;

FIGS. 5 to 8 are diagrams illustrating a manufacturing method for the diode according to the first embodiment;

FIG. 9 is a diagram of a top view illustrating a semiconductor substrate of a diode according to a modification of the first embodiment;

FIGS. 10 to 12 are diagrams of sectional views illustrating diodes according to modifications of the first embodiment;

FIG. 13 is a diagram of a sectional view illustrating a diode according to a second embodiment of the present invention;

FIGS. 14, 15 are diagrams of sectional views illustrating diodes according to modifications of the second embodiment;

FIG. 16 is a diagram of a sectional view illustrating a diode according to a third embodiment of the present invention;

FIGS. 17, 18 are diagrams of sectional views illustrating diodes according to modifications of the third embodiment;

FIG. 19 is a diagram illustrating a voltage and current density characteristic of a general Schottky diode;

FIG. 20 is a diagram illustrating a voltage and current density characteristic of a general pn junction diode;

FIG. 21 is a diagram illustrating a voltage and current density characteristic of a JBS diode;

FIG. 22 is a diagram illustrating a route of an electric current flowing via a Schottky junction in a JBS diode; and

FIG. 23 is a diagram a sectional view illustrating a JPS diode in a prior art.

### DETAILED DESCRIPTION OF THE PREFERRED EMBODIMENTS

Characteristics of embodiments according to the present invention are summarized below.

(First Characteristic)

A diode contains multiple p type semiconductor regions provided in a front face of a semiconductor substrate. The mutually adjacent p type semiconductor regions are intervened by interval spaces in the front face of the semiconductor substrate (see FIG. 2).

(Second Characteristic)

The p type semiconductor regions are formed by an epitaxial growth from a front face of the n type semiconductor region. This can help prevent the formation of defects by the ion implantation of the p type impurity. Further, in order to activate the p type semiconductor regions, it is not necessary to perform a hot heat treatment process. Further, a surface roughness due to the semiconducting material sublimating from the front face of the n type semiconductor region may be significantly prevented. Further, the leakage current may be reduced when a reverse voltage is applied (see FIG. 6).

(Third Characteristic)

The semiconducting material of the n type semiconductor region and p type semiconductor region is a silicon carbide.

### Embodiments

### 1. First Embodiment

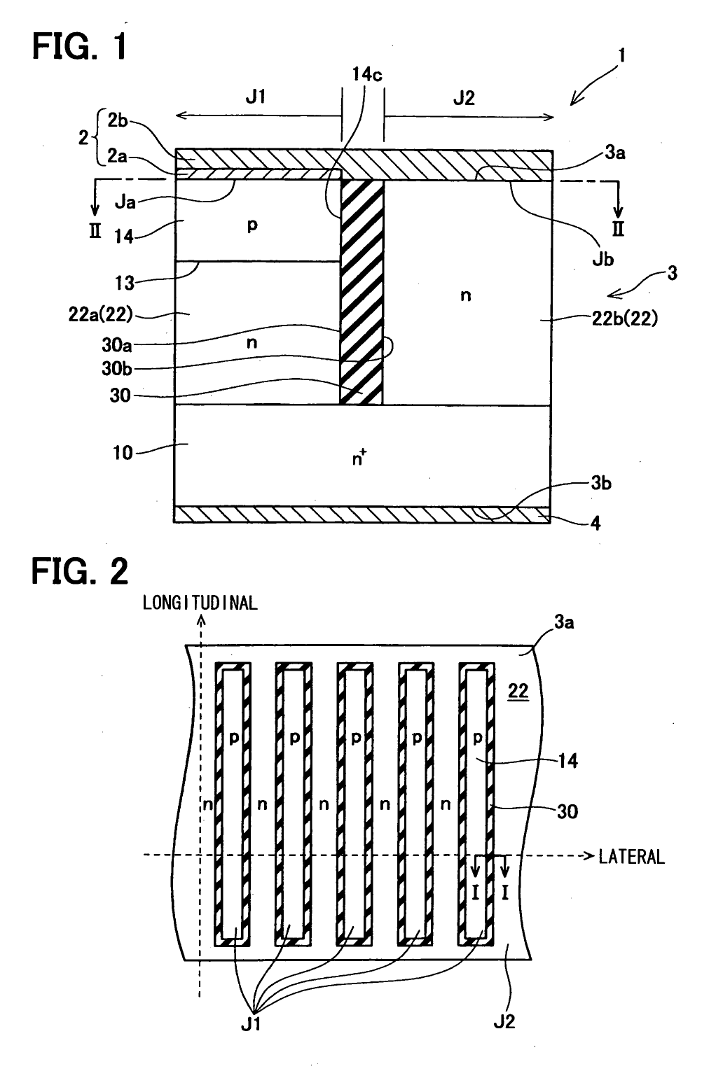

FIG. 1 illustrates a sectional view of a diode 1 in which a structure of a Schottky diode and a structure of a pn junction diode co-exist. FIG. 2 illustrates a sectional view in II-II line of FIG. 1. FIG. 2 is a plan view (i.e., in a top view) of a semiconductor substrate 3 in which the diode 1 is formed. The diode 1 illustrated in FIG. 1 is formed using the semiconductor substrate 3 of SiC. In the semiconductor substrate 3, an n⁺ type cathode region 10 (an example of an n type highly concentrated semiconductor region) and then an n type semiconductor region 22 are laminated in this order from a bottom face (i.e., rear face) to a top face (i.e., front face). The diode 1 contains a p type semiconductor region group including a plurality of p type semiconductor regions 14, which are arranged to be dispersed in a front face of the n type semiconductor region 22. As illustrated in FIG. 2, each p type semiconductor region 14 is rectangular; namely, it is long in the longitudinal direction and short in the lateral direction (i.e., traverse direction). The multiple regions 14 are arranged such that the longitudinal directions are parallel with each other to thereby form a stripe configuration or pattern. Therefore, the n type semiconductor region 22 and the p type semiconductor region 14 are repeatedly arranged (i.e., alternated with each other) in the lateral direction illustrated in FIG. 2.

The diode 1 is provided with an anode electrode 2 which adjoins the front face of the n type semiconductor region 22 and the front face of the p type semiconductor region 14 as illustrated in FIG. 1. The anode electrode 2 includes a Schottky electrode 2b as a first front face electrode and an ohmic electrode 2a as a second front face electrode. The Schottky electrode 2b forms a Schottky junction Jb to a front face of the n type semiconductor region 22. The ohmic electrode 2a forms an ohmic junction Ja to a front face of the p type semiconductor region 14. The Schottky electrode 2b is formed by (i.e., made of) molybdenum. The ohmic electrode 2a is formed by one of titanium, aluminum, and nickel, or by a lamination including at least two of titanium, aluminum, and nickel. In addition, the diode 1 is provided with a cathode electrode 4, which forms an ohmic junction to a rear face 3b of the cathode region 10 or semiconductor substrate 3.

The diode 1 is provided with a structure of a pn junction diode (referred to as a pn junction diode region J1), and a structure of a Schottky diode (referred to as a Schottky diode region J2). In the pn junction diode region J1, the cathode electrode 4, the cathode region 10, the n type semiconductor region 22, the p type semiconductor region 14, and the ohmic electrode 2a are laminated in this order from the bottom of the diode 1 as illustrated in FIG. 1. In the Schottky diode region J2, the cathode electrode 4, the cathode region 10, the n type semiconductor region 22, and then the Schottky electrode 2b are laminated in this order from the bottom of the diode 1.

The diode 1 according to the present embodiment contains an insulating region 30 provided along with a border portion between the coverage in which the Schottky junction Jb exists and the coverage in which the pn junction 13 exists. As illustrated in FIG. 1, the insulating region 30 is extended from the front face 3a of the semiconductor substrate 3 to reach the cathode region 10. The insulating region 30 divides the n type semiconductor region 22 into a first n type semiconductor region 22a and a second n type semiconductor region 22b. The first n type semiconductor region 22a is, in the pn junction diode region J1, under the p type semiconductor region 14 and adjoining a left-hand side 30a of the insulating region 30. The first n type semiconductor region 22a forms a pn junction 13 with the p type semiconductor region 14. The second n type semiconductor region 22b is, in the Schottky junction diode region J2, under the Schottky junction Jb and adjoining a right-hand side 30b of the insulating region 30. As illustrated in FIG. 2, in a top view, the insulating region 30 encloses each p type semiconductor region 14. Therefore, in a top view, the Schottky diode region J2 of the diode 1 spreads outside of the insulating region 30 whereas the pn junction diode region J1 of the diode 1 spreads inside of the insulating region 30.

In the diode 1, when a reverse voltage is applied between the anode and cathode, a depletion layer spreads from the pn junction 13. Further, when the reverse voltage is applied, a depletion layer also spreads in the second n type semiconductor region 22b, which opposes the p type semiconductor region 14 via the insulating region 30. The diode 1 has a high withstand voltage in comparison with a Schottky diode not containing a p type semiconductor region 14 in a front face of the n type semiconductor region 22.

### VOLTAGE AND CURRENT DENSITY CHARACTERISTIC OF COMPARATIVE EXAMPLE

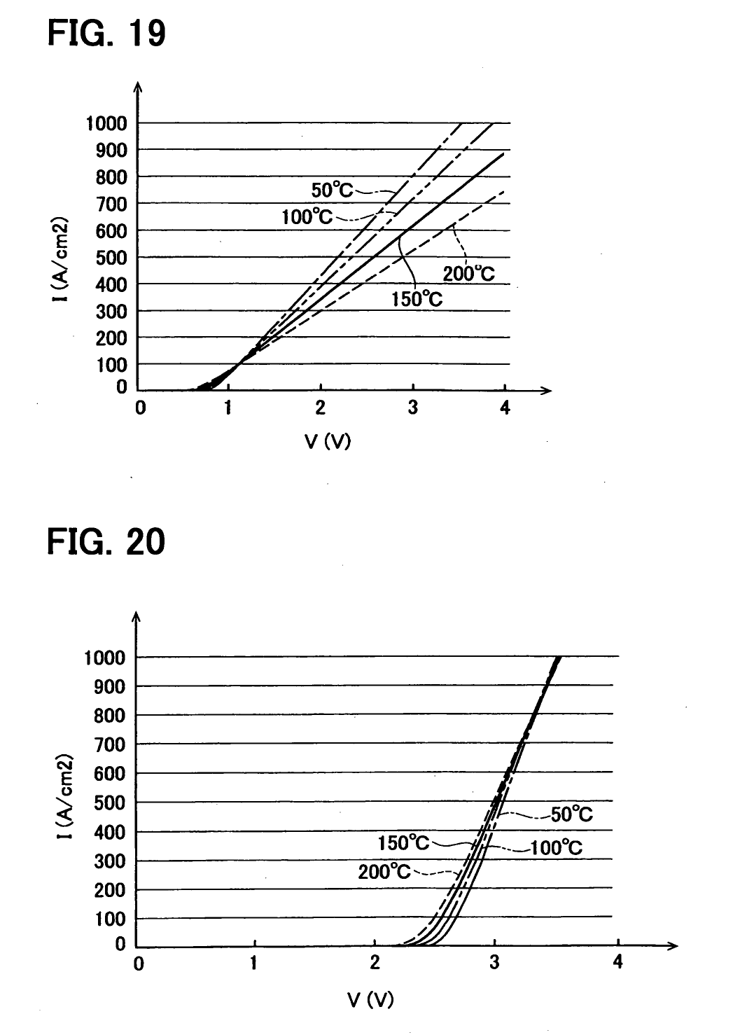

The following provides explanation of comparative examples for easily understanding the characteristic of the present embodiment. FIG. 19 illustrates a voltage and current density characteristic, which is a relation between a current density I (A/cm²) and a forward voltage V (V), which is applied between the anode and cathode of the general Schottky diode. FIG. 20 illustrates a voltage and current density characteristic of a general pn junction diode. In the general Schottky diode of FIG. 19, a p type semiconductor region is not formed in a surface layer portion of the semiconductor substrate; in contrast, a Schottky junction is formed by the n type semiconductor region and the anode electrode in the whole front face of the semiconductor substrate. The general pn junction diode of FIG. 20, a p type semiconductor region is formed in the whole surface layer portion of the semiconductor substrate; further, a pn junction is formed by the p type semiconductor region and the anode electrode in the whole front face of the semiconductor substrate. As illustrated in FIGS. 19, 20, in the Schottky diode, in comparison with the pn junction diode, an electric current can be passed through also in a range where the forward voltage is low while the forward resistance is large in a range where the forward voltage is high. In contrast, in the pn junction diode, in comparison with the Schottky diode, an electric current cannot be passed through in a range where the forward voltage is low while the forward resistance is small in a range where the forward voltage is high.

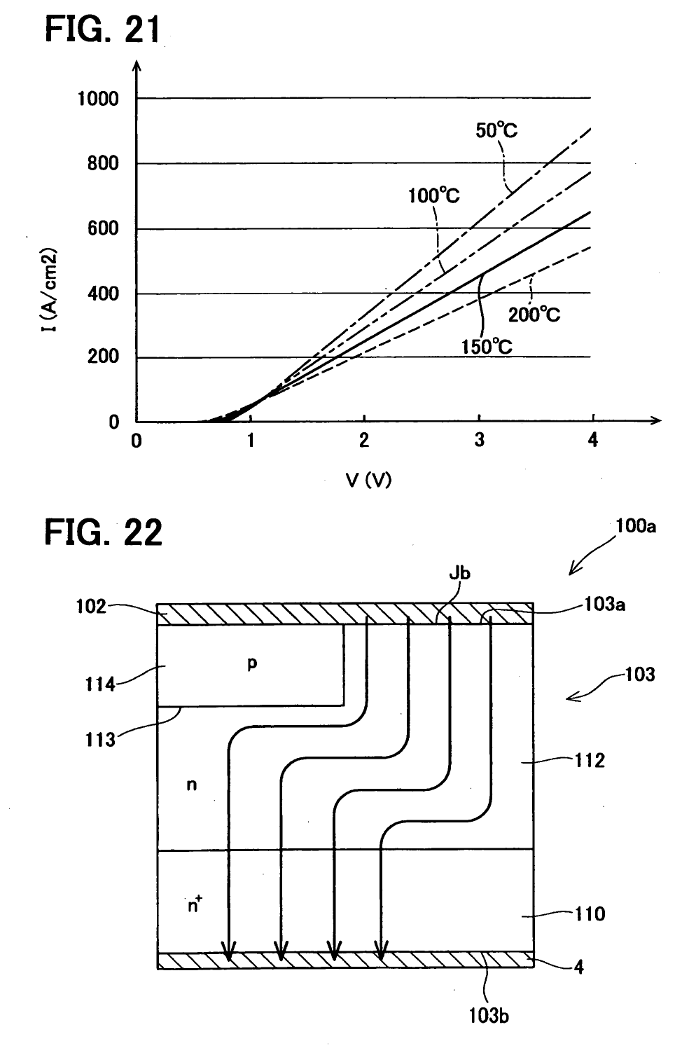

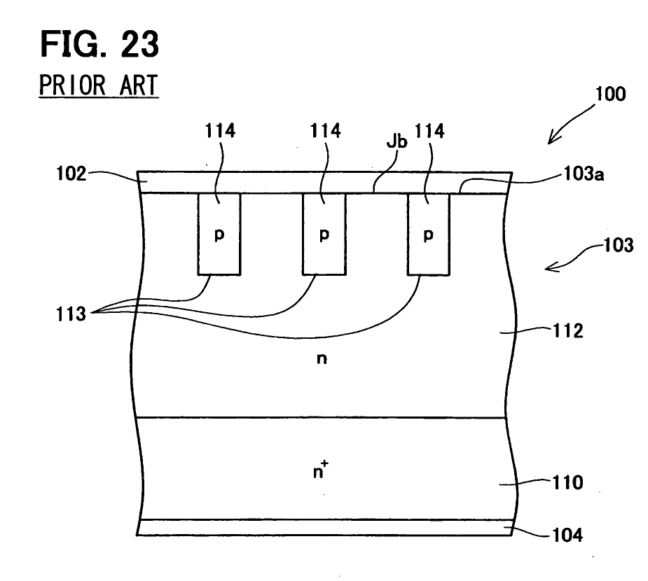

Further, in the JBS type diode 100 of FIG. 23, the pn junction is formed by the p type semiconductor region 114 and the n type semiconductor region 112. Therefore, the JBS type diode 100 contains both the structure of a Schottky diode and the structure of a pn junction diode in the surface layer portion of the semiconductor substrate 103. However, the voltage and current density characteristic of the JBS type diode 100, as illustrated in FIG. 21, is similar with the voltage and current density characteristic of the general Schottky diode illustrated in FIG. 19. That is, although the JBS type diode 100 has the pn junction formed by the p type semiconductor region 114 and the n type semiconductor region 112, the pn junction does not function substantially as a diode.

When the electric current route in the JBS type diode 100 of FIG. 23 is investigated, it became clear that the electric current route is assumed to be illustrated in FIG. 22. In the JBS type diode 100, the electric current passes first through the Schottky junction in a range of the low forward voltage. The electric current, which has flowed via the Schottky junction Jb, flows into the n type semiconductor region 112 below the p type semiconductor region 114. This increases the potential of the n type semiconductor region 112, which is located below the p type semiconductor region 114. When the potential of the n type semiconductor region 112 thus increases, the potential difference which exceeds the forward voltage drop does not occur in the pn junction 113. As a result, in a conventional JBS type diode 100, even if the forward voltage reaches a higher value, an electric current does not pass through the pn junction 113. That is, in a conventional JBS type diode 100, an electric current having passed through the Schottky junction Jb flows into the n type semiconductor region 112, which is located below the p type semiconductor region 114. Thereby, the pn junction co-existing together with the Schottky junction Jb is assumed to not substantially function as a diode. If the structure of the pn junction diode, which is formed by the p type semiconductor region 114 and the n type semiconductor region 112, were utilized, the forward resistance could be decreased in a range where the forward voltage is high. The present JBS type diode 100 thus does not provide such an advantage.

### Voltage and Current Density Characteristic of Present Embodiment

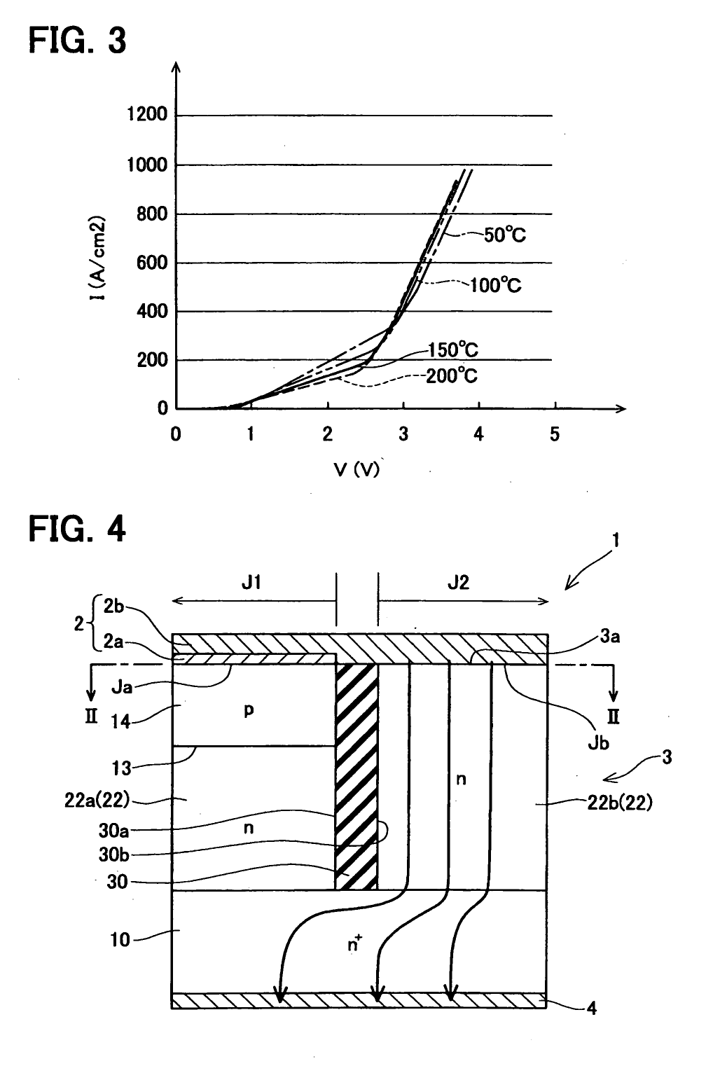

Returning to the present embodiment, when a forward voltage is applied between the anode and cathode of the diode 1, the electric current flows from the anode electrode 2 to the cathode electrode 4. FIG. 3 illustrates a voltage and current density characteristic for the diode 1. In addition, FIG. 3 illustrates the voltage and current density characteristics about the cases where the temperatures of the diode 1 are 50, 100, 150, and 200 degrees centigrade. The diode 1 indicates a gentle slope under the above temperatures in a lower forward voltage range up to about 2.5 (V). In contrast, the diode 1 indicates a steep slope under the above temperatures in a higher forward voltage range.

As compared with the pn junction diode region J1, the Schottky diode region J2 containing the structure of the Schottky diode is conductive when a forward voltage V (V) is low. In a range of the low forward voltage V (V), the Schottky diode region J2 is conductive while the pn junction diode region J1 is not conductive. Accordingly, in the range of the low forward voltage V (V), the slope of the graph is gentle. In the range of the high forward voltage V (V), in addition to the Schottky diode region J2, the pn junction diode region J1 containing the structure of the pn junction diode is also conductive. Accordingly, in the range of the high forward voltage V (V), the slope of the graph becomes steep, thus increasing the current density I (A/cm²).

FIG. 4 illustrates a state where only the Schottky diode region J2 is conductive when the forward voltage is applied. The electric current flows from the Schottky electrode 2b through the Schottky junction Jb, the second n type semiconductor region 22b, and the cathode region 10 into the cathode electrode 4. The diode 1 contains the insulating region 30; thus, the electric current passing through the Schottky junction Jb does not enter the first n type semiconductor region 22a, which is located under the p type semiconductor region 14. In other words, since the electric current having passed through the Schottky junction Jb does not enter the first n type semiconductor region 22a, the electric potential of the first n type semiconductor region 22a does not easily increase. The pn junction 13 can be easily supplied with a sufficient voltage exceeding the forward voltage drop. As illustrated in FIG. 3, at a forward voltage of about 3 (V), the pn junction 13 becomes conductive, thereby allowing the electric current to flow through the pn junction diode region J1. The electric current flows from the ohmic electrode 2a via the ohmic junction Ja, the p type semiconductor region 14, the first n type semiconductor region 22a, and the cathode region 10 then to the cathode electrode 4. According to the diode 1, in a range of the high forward voltage V (V), the current density I (A/cm²) can be increased and the forward resistance can be reduced.

According to the diode 1 of the present embodiment, while the use of the Schottky diode region J2 allows the electric current to flow even when the forward voltage V (V) is within a low value range, the use of the pn junction diode region J1 allows the forward resistance to decrease when the forward voltage V (V) is within a high value range.

Furthermore, in a general Schottky diode, the current density has temperature dependency especially in the range of the high forward voltage V (V), as illustrated in FIG. 19. In the range of the high forward voltage V (V), a variation of the forward resistance due to the temperature change becomes large. That is, the Schottky diode tends to be affected by the temperature. In contrast, in a general pn junction diode, the forward resistance cannot be easily affected by the temperature, even if the forward voltage V (V) is in the high value range, as illustrated in FIG. 20. According to the diode 1 of the present embodiment, in a range of the high forward voltage V (V), the pn junction diode region J1 which has a structure of the pn junction diode carries out conduction. Thereby, the diode 1 cannot be easily affected by the temperature in a range of the high forward voltage V (V).

Further, the insulating region 30 of the diode 1 is arranged, in a top view, along the border 14c between the coverage where the Schottky junction Jb exists and the coverage where the pn junction 13 exists. This helps prevent an occurrence of the phenomenon that the electric current, which has passed through the Schottky junction Jb, flows in the whole of the first n type semiconductor region 22a located below the p type semiconductor region 14. Most of the pn junction 13 formed by the p type semiconductor region 14 and first n type semiconductor region 22a can be utilized as a pn junction diode. The forward resistance can be thus significantly reduced in the range where the forward voltage is high.

In the diode 1, multiple p type semiconductor regions 14 are dispersed in the semiconductor substrate 3. When the reverse voltage is applied, the depletion layer can be lengthened from the multiple pn junctions 13. The withstand voltage of the diode 1 can be thus raised further.

In addition, the insulating region 30 of the diode 1 is extended to reach the cathode region 10. In the diode 1, the insulating region 30 separates, from each other, the second n type semiconductor region 22b, which is located under the Schottky junction Jb, and the first n type semiconductor region 22a, which is located under the p type semiconductor region 14. The electric current which flows via the Schottky junction Jb does not enter the first n type semiconductor region 22a. The electric potential of the first n type semiconductor region 22a does not rise by an electric current flowing via the Schottky junction Jb. This allows application of a voltage exceeding the forward voltage drop in the pn junction 13 formed by the p type semiconductor region 14 and the first n type semiconductor region 22a.

The diode 1 of the present embodiment is provided with the Schottky electrode 2b which abuts to the front face of the n type semiconductor region 22. Further, the diode 1 of the present embodiment is provided with the ohmic electrode 2a which abuts to the front face of the p type semiconductor region 14. A potential difference does not arise approximately between the p type semiconductor region 14 and the ohmic electrode 2a. This can enlarge more the potential difference of the pn junction 13, which is formed by the p type semiconductor region 14 and the first n type semiconductor region 22a. Also in a range of the comparatively low forward voltage V (V), the pn junction 13 can be effectively operated as a pn junction diode.

(Manufacturing Process)

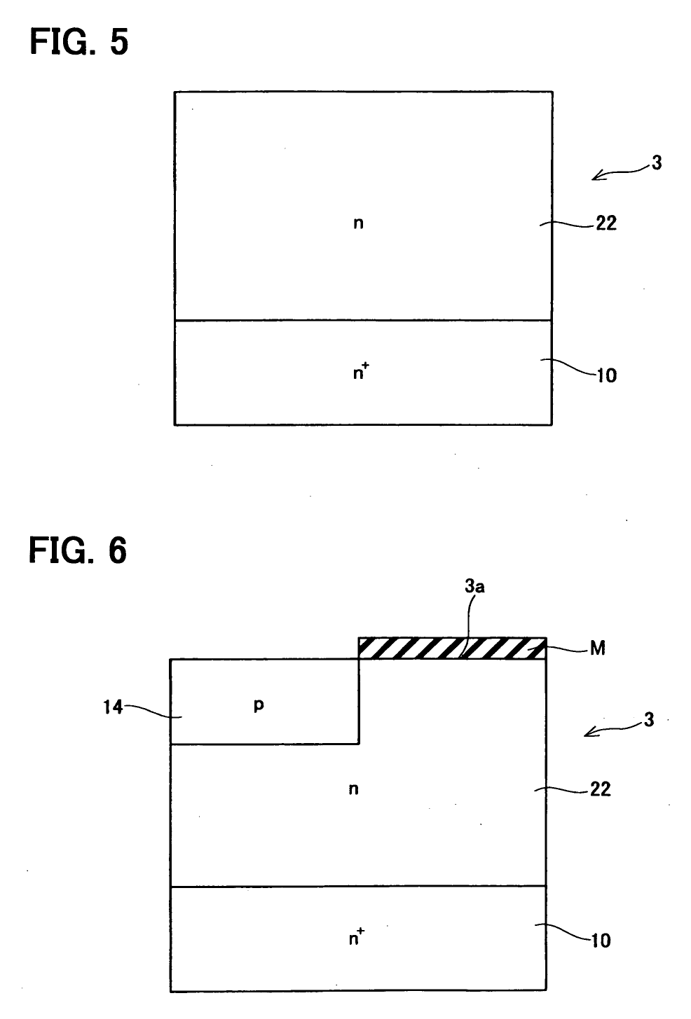

Next, the following explains a process, which is characteristic in the manufacturing method for the diode 1, with reference to FIGS. 5 to 8. First, an n⁺ type SiC substrate used as the cathode region 10 is prepared. The concentration of the n type impurity of the cathode region 10 is set to 1×10¹⁸/cm³. The thickness of the cathode region 10 is set to 350 micrometers. Next, as illustrated in FIG. 5, a crystal growth of the n type semiconductor region 22 having a thickness of 15 micrometers is performed in a front face of the n⁺ type cathode region 10. The crystal growth is performed at a temperature of 1500 degrees centigrade. Materials for the crystal growth include SiH4, C3H8, N2, and H2. Thus, the n type semiconductor region 22 is formed with the concentration of the n type impurity of 5×10¹⁵/cm³. In the present embodiment, the cathode region 10 and the n type semiconductor region 22 are collectively called the semiconductor substrate 3.

Next, as illustrated in FIG. 6, a mask M is formed so as to have an opening in the front face 3a of the semiconductor substrate 3. An ion implantation of the p type impurity with a low diffusion coefficient, such as aluminum, is performed to the n type semiconductor region 22 via the opening of the mask M. In order to activate the implanted p type impurity, a heat treatment is performed, for example, at a temperature of 1600 degrees centigrade. This enables the formation of the p type semiconductor region 14 with the impurity concentration of 1×10²⁰/cm³ at the opening of the mask M. The p type semiconductor region 14 has a width (the length in the lateral direction in FIG. 2) of 2.0 micrometers and a length (the length of the longitudinal direction in FIG. 2) of 5.0 micrometers on the front face 3a while having a depth of 0.3 to 1.0 micrometer from the front face 3a. The mask M is then removed.

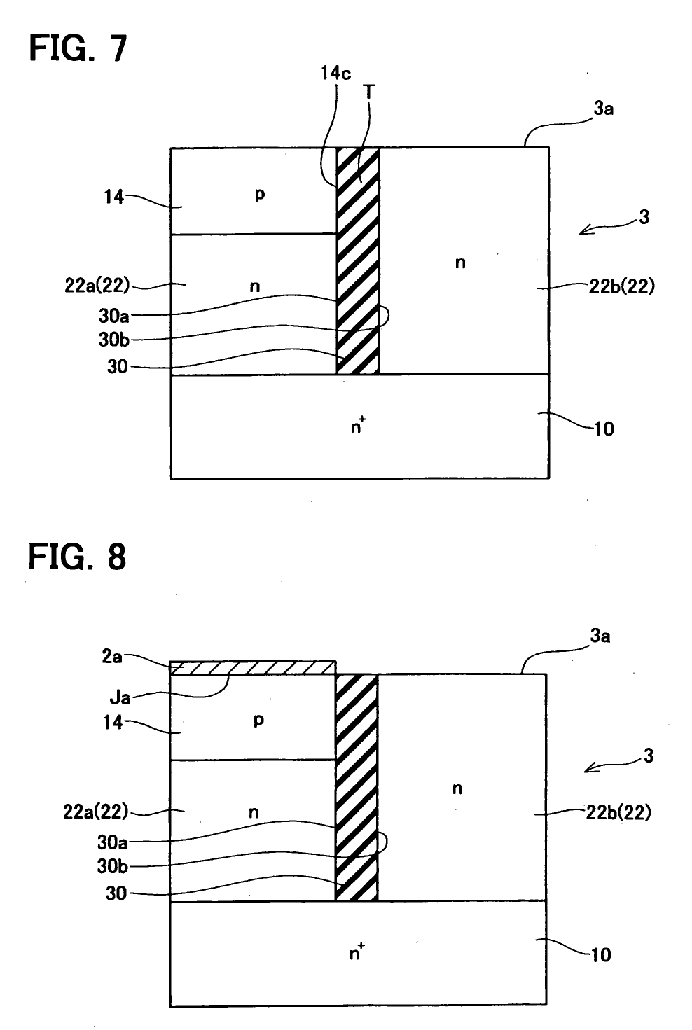

Next, a trench T is formed in a border 14c of a coverage in which the Schottky junction Jb exists and a coverage in which the pn junction 13 exists, as illustrated in FIG. 7. The trench T is formed, for example, with a dry etching (ICP etc.). The trench T is formed from the front face 3a to reach the cathode region 10. Next, an insulating layer, such as an oxide film and a nitride, is formed inside of the trench T with the CVD (Chemical Vapor Deposition) method. For example, the oxide film is formed in the trench T with the plasma CVD. Thereby, the insulating region 30 is formed. The insulating region 30 thus divides the n type semiconductor region 22 into the first n type semiconductor region 22a and the second n type semiconductor region 22b.

Next, a nickel layer is laminated by the electron beam evaporation applied on the front face 3a. As illustrated in FIG. 8, the patterning of a layered product is performed such that the layered product remains only in the front face of the p type semiconductor region 14. The ohmic electrode 2a which forms an ohmic junction Ja with the p type semiconductor region 14 is thus formed by the layered product on the front face of the p type semiconductor region 14.

Next, an electron beam evaporation of molybdenum is performed to the entire front face, which is exposed as illustrated in FIG. 8. The Schottky electrode 2b is thus formed as illustrated in FIG. 1. While the Schottky electrode 2b is provided to form the Schottky junction Jb with the second n type semiconductor region 22b, the Schottky electrode 2b is connected with the ohmic electrode 2a. The anode electrode 2 is formed to include the ohmic electrode 2a and Schottky electrode 2b. The front face of the anode electrode 2 is made flat. Next, a nickel layer is vapor-deposited at the rear face 3b of the semiconductor substrate 3 and heat-treated to thereby form the cathode electrode 4.

The insulating region 30 of the diode 1 of the present embodiment is extended in the depth direction from the front face 3a of the semiconductor substrate 3. The above insulating region 30 is provided by forming the trench T with etching from the front face 3a of the semiconductor substrate 3 and by filing up the trench T with an insulator. Therefore, according to the diode 1 of the present embodiment, it is easy to form the insulating region 30.

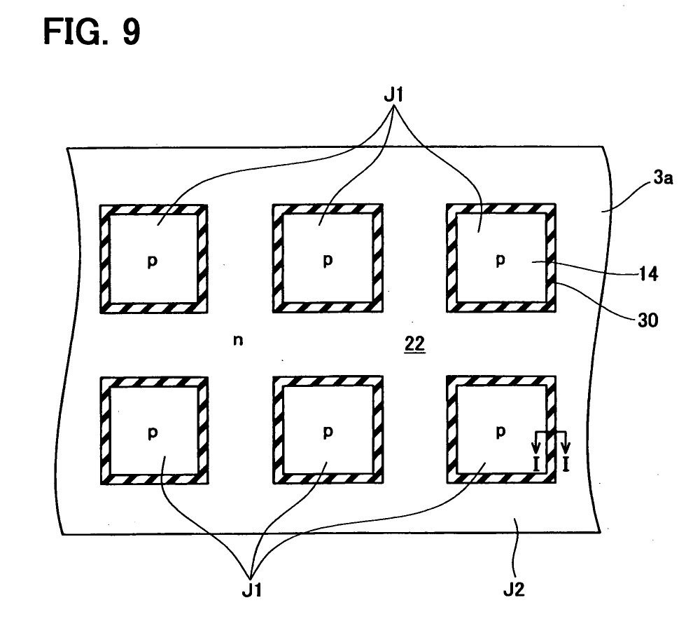

In the present embodiment, as illustrated in FIG. 2, multiple rectangular p type semiconductor regions 14 are arranged, in a top view, such that the longitudinal directions of the regions 14 are parallel with each other to thereby form a stripe configuration or pattern. As illustrated in a top view of FIG. 9, multiple p type semiconductor regions 14 may be arranged so as to look like a configuration or group of dispersed islands. Also in this case, the insulating region 30 may be formed to surround each of the multiple p type semiconductor regions 14.

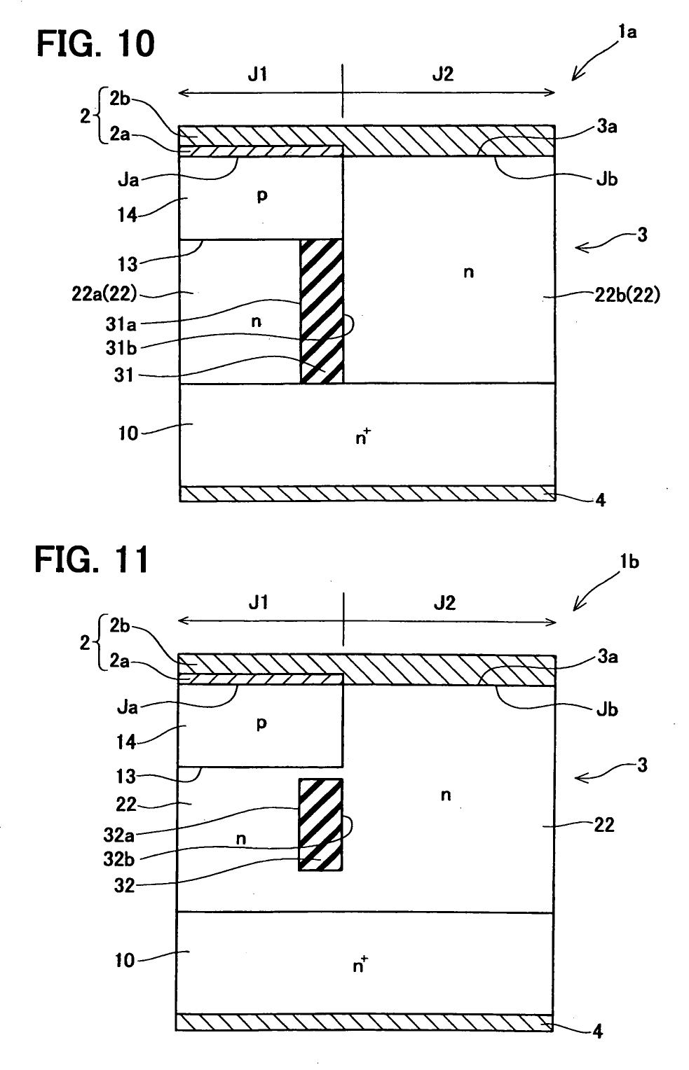

Further, in the present embodiment, the insulating region 30 of the diode 1 is arranged, in a top view, along the border 14c between the coverage where the Schottky junction Jb exists and the coverage where the pn junction 13 exists. However, the configuration of the insulating region is not limited to the above present embodiment. For example, as shown in a diode 1a in FIG. 10, an insulating region 31 may be provided to be extended from the bottom of the p type semiconductor region 14 to the front face of the cathode region 10. A right-hand side 31b (an example of the first side) of the insulating region 31 opposes the n type semiconductor region 22 which is located under the Schottky junction Jb. A left-hand side 31a (an example of the second side) of the insulating region 31 opposes the n type semiconductor region 22 which is located under the pn junction 13. Similarly, when the forward voltage is applied, the existence of the insulating region 31 can also help prevent the electric current having passed through the Schottky junction Jb from flowing into the n type semiconductor region 22 under the p type semiconductor region 14. The insulating region 31 may be desirably arranged, in a top view, near a peripheral border of the p type semiconductor region 14, i.e., near a border portion interleaved between a coverage where the Schottky junction Jb exists and a coverage where the pn junction 13 exists.

Further, for example, as shown in a diode 1b in FIG. 11, an insulating region 32 may be provided to be extended in a depth direction within the n type semiconductor region 22 below the p type semiconductor region 14. The insulating region 32 is not in contact with the bottom of the p type semiconductor region 14. The insulating region 32 is not extended to reach the cathode region 10. A right-hand side 32b (an example of the first side) of the insulating region 32 opposes the n type semiconductor region 22 which is located under the Schottky junction Jb. A left-hand side 32a (an example of the second side) of the insulating region 32 opposes the n type semiconductor region 22 which is located below the pn junction 13. Similarly, when the forward voltage is applied, the existence of the insulating region 32 can also help prevent the electric current having passed through the Schottky junction Jb from flowing into the n type semiconductor region 22 under the p type semiconductor region 14. Herein, the insulating region 32 may be abut to the bottom of the p type semiconductor region 14. The insulating region 32 may be extended to reach the cathode region 10. The insulating region 32 may be desirably arranged, in a top view, near a peripheral border of the p type semiconductor region 14.

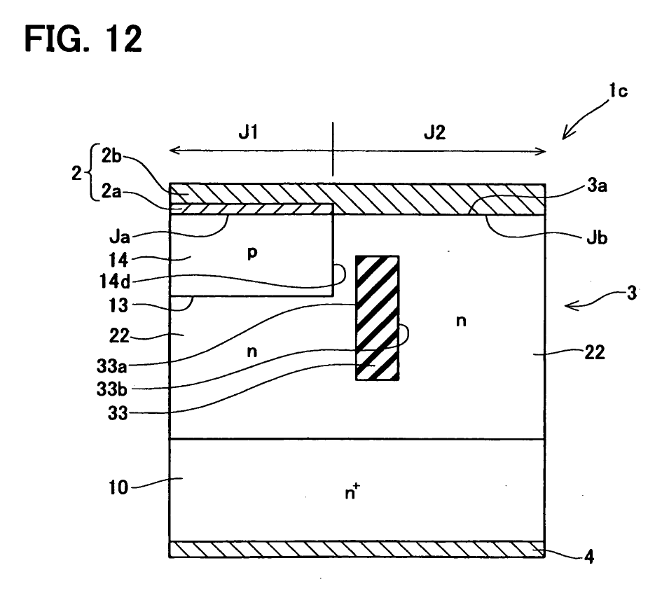

Further, for example, as shown in a diode 1c in FIG. 12, an insulating region 33 may be provided to be extended in a depth direction within the n type semiconductor region 22 below the Schottky junction Jb. The insulating region 33 is not in contact with the Schottky junction Jb. The insulating region 33 is not extended to reach the cathode region 10. In addition, the insulating region 33 is spaced out with a side 14d of the p type semiconductor region 14. A right-hand side 33b (an example of the first side) of the insulating region 33 opposes the n type semiconductor region 22 which is located below the Schottky junction Jb. A left-hand side 33a (an example of the second side) of the insulating region 33 opposes the n type semiconductor region 22 which is located below the pn junction 13. Similarly, when the forward voltage is applied, the existence of the insulating region 33 can also help prevent the electric current having passed through the Schottky junction Jb from flowing into the n type semiconductor region 22 below the p type semiconductor region 14. The insulating region 33 may be in contact with the Schottky junction Jb. The insulating region 33 may be extended to reach the cathode region 10. The insulating region 33 may be desirably arranged, in a top view, near a peripheral border of the p type semiconductor region 14.

### 2. Second Embodiment

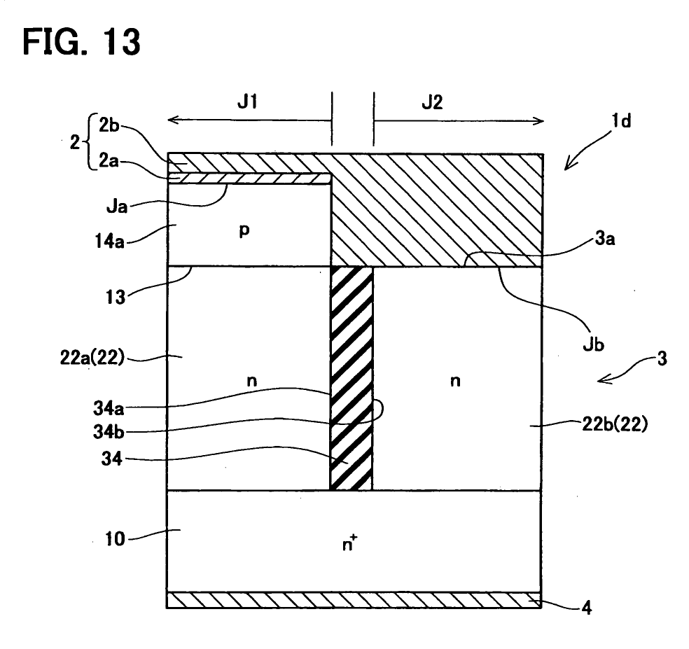

FIG. 13 illustrates a sectional view of a diode 1d in which a structure of a Schottky diode and a structure of a pn junction diode co-exist. The diode 1d of the present embodiment has a characteristic that a p type semiconductor region 14a is arranged on a front face 3a of the semiconductor substrate 3. Herein, in FIG. 13, components comparable with those of FIG. 1 are assigned with the same reference numbers as those in FIG. 1. Explanation is omitted for such comparable components.

The diode 1d contains multiple p type semiconductor regions 14a provided in a front face of the n type semiconductor region 22. The pn junction 13 is formed within, of a front face 3a of the semiconductor substrate 3, a range where the p type semiconductor region 14a is arranged. The ohmic electrode 2a which forms an ohmic junction Ja with each p type semiconductor region 14a is formed on a front face of each p type semiconductor region 14a. The Schottky electrode 2b forms a Schottky junction Jb with the n type semiconductor region 22 within a range where the p type semiconductor region 14a is not arranged. The Schottky electrode 2b is further provided to cover the ohmic electrode 14a as illustrated in FIG. 13. The anode electrode 2 is thus formed by the ohmic electrode 2a and Schottky electrode 2b. The front face of the anode electrode 2 is made flat.

In the pn junction diode region J1 of the diode 1d, the cathode electrode 4, the cathode region 10, the n type semiconductor region 22, the p type semiconductor region 14a, and the ohmic electrode 2a are laminated in this order from the bottom in FIG. 13. In the Schottky diode region J2, the cathode electrode 4, the cathode region 10, the n type semiconductor region 22, and the Schottky electrode 2b are laminated in this order from the bottom in FIG. 13.

The diode 1d according to the present embodiment contains an insulating region 34 so as to be arranged, in a top view, in a border region between a coverage in which the Schottky junction Jb exists and a coverage in which the pn junction 13 exists. The insulating region 34 is extended from the front face 3a of the semiconductor substrate 3 to reach the cathode region 10. The insulating region 34 divides the n type semiconductor region 22 into a first n type semiconductor region 22a and a second n type semiconductor region 22b. The first n type semiconductor region 22a is, in the pn junction diode region J1, under the p type semiconductor region 14a and adjoining a left-hand side 34a (an example of the second side) of the insulating region 34. The first n type semiconductor region 22a forms the pn junction 13 with the p type semiconductor region 14a. The second n type semiconductor region 22b is, in the Schottky junction diode region J2, below the Schottky junction Jb and adjoining a right-hand side 34b (an example of the first side) of the insulating region 34. In a top view, the insulating region 34 encloses the first n type semiconductor region 22a. Therefore, in a top view, the Schottky diode region J2 spreads outside of the insulating region 34. The pn junction diode region J1 spreads inside of the insulating region 34.

According to the diode 1d, when the forward voltage is applied, the electric current having passed through the Schottky junction Jb does not enter the first n type semiconductor region 22a, which is located under the p type semiconductor region 14a. The pn junction 13 can be relatively easily supplied with a voltage exceeding the forward voltage drop.

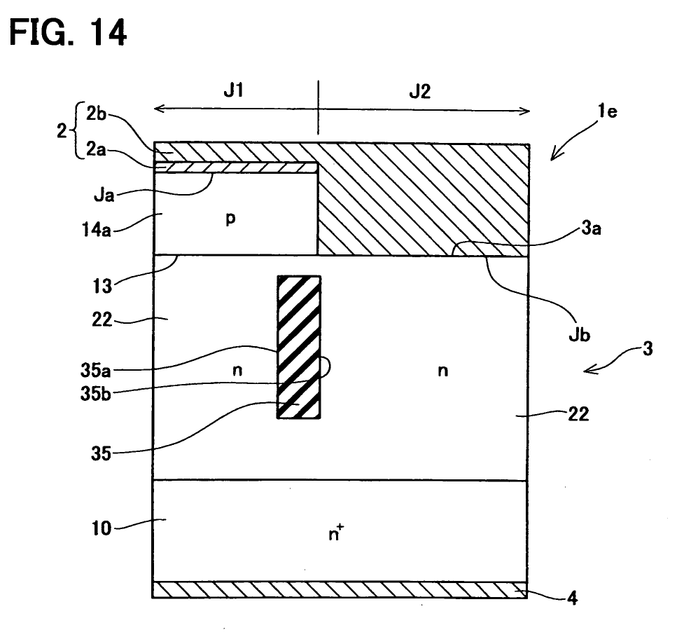

In the present embodiment, the insulating region 34 is extended from the front face 3a of the semiconductor substrate 3 to reach the cathode region 10. However, the configuration of the insulating region is not limited to the above present embodiment. For example, as shown in a diode 1e in FIG. 14, an insulating region 35 may be provided to be extended in a depth direction within the n type semiconductor region 22 below the p type semiconductor region 14a. The insulating region 35 is not in contact with the bottom of the p type semiconductor region 14a. The insulating region 35 is not extended to reach the cathode region 10. A right-hand side 35b (an example of the first side) of the insulating region 35 opposes the n type semiconductor region 22 which is located below the Schottky junction Jb. A left-hand side 35a (an example of the second side) of the insulating region 35 opposes the n type semiconductor region 22 which is located below the pn junction 13. Similarly, when the forward voltage is applied, the existence of the insulating region 35 can also help prevent the electric current having passed through the Schottky junction Jb from flowing into the n type semiconductor region 22 under the p type semiconductor region 14a. The insulating region 35 may be in contact with the bottom of the p type semiconductor region 14a. The insulating region 35 may be extended to reach the cathode region 10. The insulating region 35 may be desirably arranged, in a top view, near a peripheral border of the p type semiconductor region 14a.

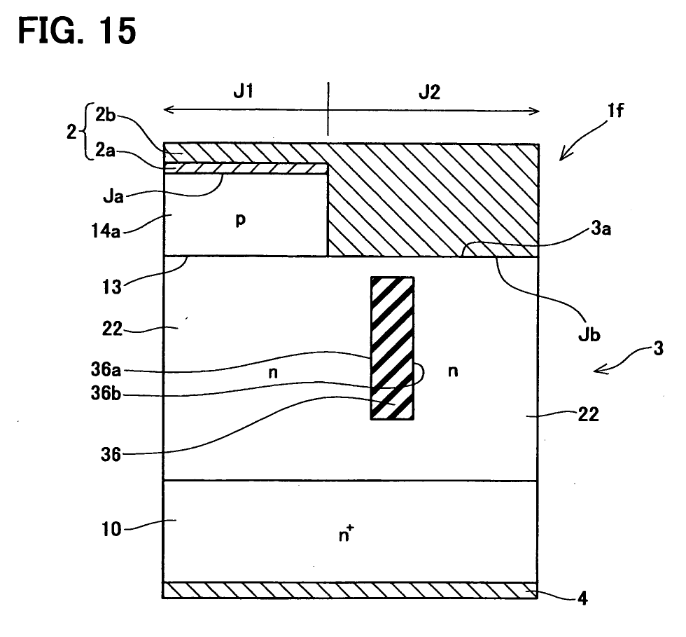

Further, for example, as shown in a diode If in FIG. 15, an insulating region 36 may be provided to be extended in a depth direction within the n type semiconductor region 22 below the Schottky junction Jb. The insulating region 36 is not in contact with the Schottky junction Jb. The insulating region 36 is not extended to reach the cathode region 10. In addition, the insulating region 36 is spaced out with a position below the p type semiconductor region 14a. A right-hand side 36b (an example of the first side) of the insulating region 36 opposes the n type semiconductor region 22 which is located below the Schottky junction Jb. A left-hand side 36a (an example of a second side) of the insulating region 36 opposes the n type semiconductor region 22 which is located below the pn junction 13. Similarly, when the forward voltage is applied, the existence of the insulating region 36 can also help prevent the electric current having passed through the Schottky junction Jb from flowing into the n type semiconductor region 22 under the p type semiconductor region 14a. The insulating region 36 may be in contact with the Schottky junction Jb. The insulating region 36 may be extended to reach the cathode region 10. The insulating region 36 may be desirably arranged, in a top view, near a position below the p type semiconductor region 14a.

### 3. Third Embodiment

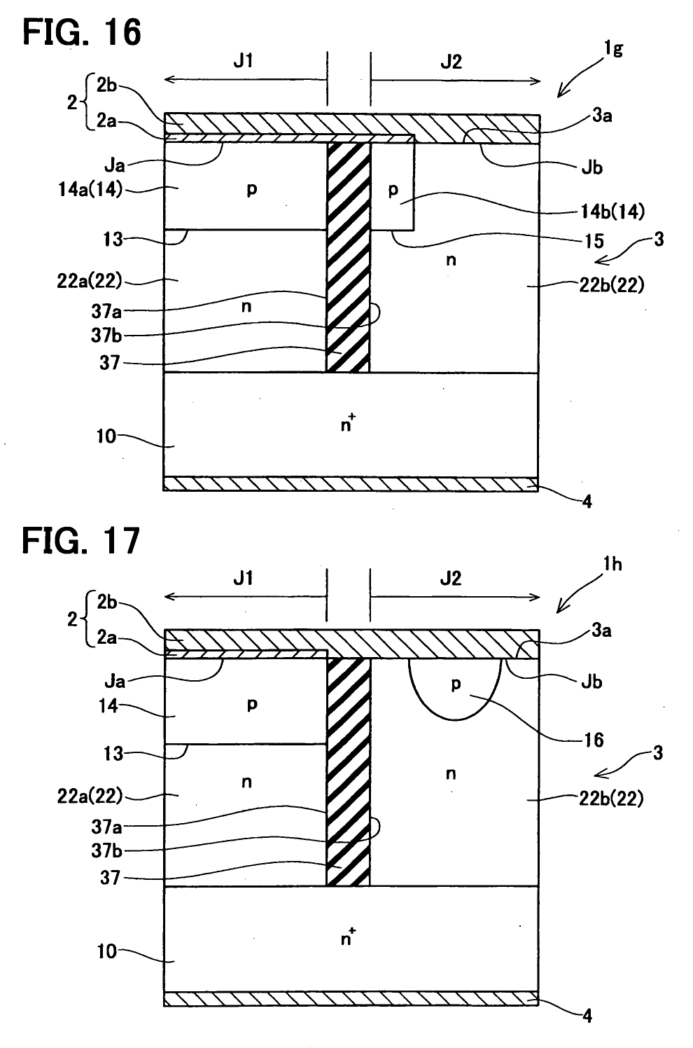

FIG. 16 illustrates a sectional view of a diode 1g in which a structure of a Schottky diode and a structure of a pn junction diode co-exist. The diode 1g of the present embodiment has a characteristic that an insulating region 37 penetrates the p type semiconductor region 14. Herein, in FIG. 16, components comparable with those of the diode 1 in FIG. 1 are assigned with the same reference numbers as those in FIG. 1. Explanation is omitted for such comparable components.

The diode 1g of the present embodiment contains the insulating region 37 which penetrates the p type semiconductor region 14. The insulating region 37 is formed near a peripheral border of the p type semiconductor region 14. The insulating region 37 is extended from the front face 3a of the semiconductor substrate 3 to reach the cathode region 10. The insulating region 37 divides the n type semiconductor region 22 into the first n type semiconductor region 22a and the second n type semiconductor region 22b. The first n type semiconductor region 22a is, in the pn junction diode region J1, below the p type semiconductor region 14 and adjoining a left-hand side 37a (an example of the second side) of the insulating region 37. The first n type semiconductor region 22a forms the pn junction 13 with the p type semiconductor region 14. The second n type semiconductor region 22b is, in the Schottky junction diode region J2, below the Schottky junction Jb and adjoining a right-hand side 37b (an example of the first side) of the insulating region 37. In addition, the p type semiconductor region 14 is divided by the insulating region 37 into the first p type semiconductor region 14a covered by the pn junction diode region J1, and the second p type semiconductor region 14b covered by the Schottky diode region J2. In the diode 1g, the ohmic electrode 2a is extended to cover the front face of the first p type semiconductor region 14a, the front face of the insulating region 37, and the front face of the second p type semiconductor region 14b.

In the diode 1g of the present embodiment, the second p type semiconductor region 14b and the second n type semiconductor region 22b under the Schottky junction Jb abut to each other. A depletion layer can be extended from a pn junction plane 15 formed between the second n type semiconductor region 22b and the second p type semiconductor region 14b. The depletion layer is apt to spread easily near the Schottky junction plane Jb, and the high withstand voltage can be obtained.

The insulating region 37 in the diode 1g can be easily formed, for instance, as follows. A p type diffusion layer is formed in a front face of an n type semiconductor region 22. A trench is formed to penetrate the p type diffusion layer from the front face 3a. The trench is filled up with an insulating layer.

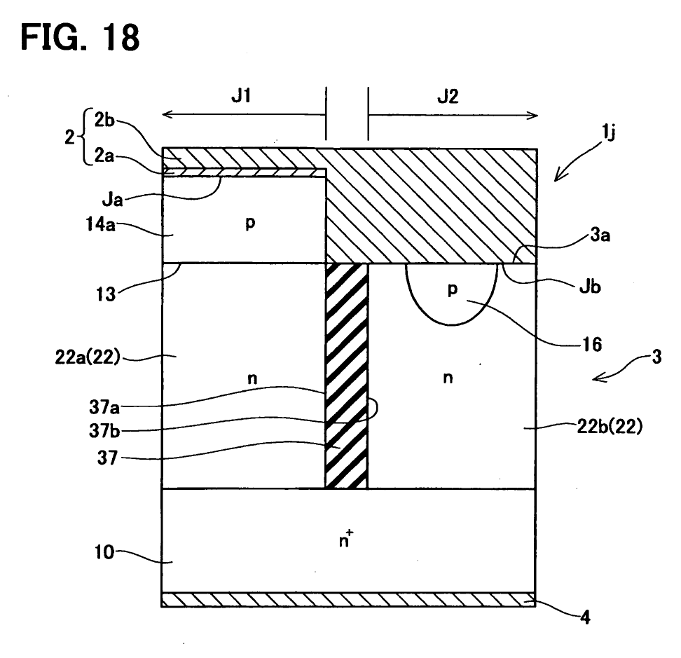

As illustrated in a diode 1h of FIG. 17, an insulating region 37 and a p type diffused region 16 may be spaced out from each other. When a reverse voltage is applied, a depletion layer can spread from the pn junction between the p type diffused region 16 and second n type semiconductor region 22b. When a reverse voltage is applied, a depletion layer can be relatively easily spread near a Schottky junction Jb. However, according to such a configuration, when forming the p type diffused region 16, the planar dimension of the area of Schottky junction Jb is apt to decrease. Accordingly, the p type diffused region, which forms a pn junction with the second n type semiconductor region 22b located below the Schottky junction Jb, may be desirably arranged to abut to the insulating region 37, like the p type semiconductor region 14b illustrated in FIG. 16. However, when the planar dimensions of the area of the Schottky junction Jb can be obtained enough, a configuration illustrated in FIG. 17 may be used. FIG. 18 illustrates a diode 1j containing a p type semiconductor region 14a arranged on a front face 3a of the semiconductor substrate 3. In such a configuration, the above explanation relative to the position of the p type diffused region 16 can be made similarly.

In the present embodiment, as illustrated in FIG. 16, the ohmic electrode 2a is extended to cover the front face of the first p type semiconductor region 14a, the front face of the insulating region 37, and the front face of the second p type semiconductor region 14b. However, the ohmic electrode 2a may not need to cover the front face of the insulating region 37 and the front face of the second p type semiconductor region 14b. Even if the second p type semiconductor region 14b adjoins the Schottky electrode 2b, a depletion layer can spread from the pn junction between the second n type semiconductor region 22b and the second p type semiconductor region 14b.

### 4. Other Modifications

The first to third embodiments explain the case that the semiconductor substrate 3 is made of SiC. The material for the semiconductor substrate 3 may be made of another material such as Si. The first to third embodiments explain the case that the anode electrode 2 includes the ohmic electrode 2a forming an ohmic junction Ja with the p type semiconductor region 14, and the Schottky electrode 2b forming a Schottky junction Jb with the n type semiconductor region 22. The anode electrode 2 may not include any ohmic electrode 2a. If at least an insulating region in any one of the first to third embodiments is provided in a diode, the pn junction diode region J1 can be utilizable.

In addition, the insulating region 30 may be formed so as to reach the rear face 3b of the semiconductor substrate 3. Further, the first to third embodiments explain the case that the front face of the thick Schottky electrode 2b is made flat. The Schottky electrode 2b may be formed as a film of thin molybdenum, for example. In such a case, it is desirable to form a front face wiring with aluminum etc. on the molybdenum film, and then make flat the front face of the front face wiring.

### 5. Aspect of Disclosure

Aspects of the disclosure described herein are set out in the following clauses.

An aspect of the disclosure is characterized in that, so as to help prevent an electric current having passed through a Schottky junction from flowing into an n type semiconductor region below a p type semiconductor region, an insulating region is provided in an n type semiconductor region. The insulating region is arranged between the Schottky junction and the n type semiconductor region, which is located below the p type semiconductor region. This helps prevent the phenomenon that the electric current having passed through the Schottky junction flows into the n type semiconductor region below the p type semiconductor region while generating a potential difference exceeding a forward voltage drop in the pn junction formed by the p type semiconductor region and n type semiconductor region. Accordingly, in a range of a high forward voltage, the pn junction is conductive while achieving a low forward resistance.

That is, the diode according to the aspect of the present disclosure is provided with an n type semiconductor region, a p type semiconductor region, a front face electrode, and an insulating region. The p type semiconductor region is arranged in a portion of a front face of the n type semiconductor region. The front face electrode adjoins a front face of the n type semiconductor region and a front face of the p type semiconductor region. In addition, the front face electrode forms at least a Schottky junction on a front face of the n type semiconductor region. The front face electrode may form a Schottky junction or an ohmic junction, in the front face of the p type semiconductor region. The insulating region has a first side and a second side, each of which adjoins the n type semiconductor region. The first side faces the n type semiconductor region which is located below the Schottky junction. The second side faces the n type semiconductor region, which is located below the pn junction formed between the p type semiconductor region and the n type semiconductor region.

Herein, a Schottky junction signifies a junction in which a Schottky barrier exists between the semiconductor and the front face electrode. In the Schottky junction, a difference arises between the barrier height of the semiconductor and the barrier height of the front face electrode.

In the above-mentioned diode, when a forward voltage is applied to the diode, an electric current, which flows via the Schottky junction, is obstructed by the insulating region. This controls the phenomenon that the electric current flows into the n type semiconductor region which is located below the p type semiconductor region while generating a potential difference exceeding a forward voltage drop in the pn junction formed by the p type semiconductor region and n type semiconductor region. Thereby, the structure of the pn junction diode can be conductive and utilized. The reduction of a forward resistance of the diode can be therefore achieved.

As an optional aspect, in a top view, the insulating region may be arranged along a border portion interleaved between a coverage where the Schottky junction exists and a coverage where the pn junction exists. Herein, without need to limit the border portion to a border face or plane, the border portion may include an area near the border face. According to the above-mentioned configuration, the insulating region is arranged along with a peripheral border of the p type semiconductor region. This helps prevent an occurrence of the phenomenon that the electric current, which has passed through the Schottky junction, flows into the whole of the n type semiconductor region located below the p type semiconductor region. Most of the pn junction formed by the p type semiconductor region and n type semiconductor region can be utilized as a pn junction diode. The forward resistance can be significantly reduced in the range where the forward voltage is high.

As an optional aspect, the n type semiconductor region and the p type semiconductor region may be provided in a semiconductor substrate. In such a case, the n type semiconductor region and the p type semiconductor region may be repeatedly arranged (i.e., are alternated with each other) at least along one direction in the surface layer portion of the semiconductor substrate. In addition, the front face electrode may be provided above the semiconductor substrate. In the above configuration, more than one p type semiconductor region is dispersed in the surface layer portion of the semiconductor substrate. When the reverse voltage is applied, the depletion layer can be lengthened from more than one pn junction. The withstand voltage of the diode can be raised further.

As an optional aspect, the insulating region may be extended from the front face of the semiconductor substrate to a position deeper than the p type semiconductor region. The above insulating region may be obtained by the following process. A trench is formed by etching from a front face of the semiconductor substrate and filled up with an insulator. The insulating region of the above configuration has a feature of being easy to manufacture.

As an optional aspect, the insulating region may penetrate the p type semiconductor region. According to the above configuration, the p type semiconductor region is divided by the insulating region. A part of the divided p type semiconductor region is formed in a part of the front face of the n type semiconductor region which is located below the Schottky junction. When the reverse voltage is applied, the depletion layer can be extended from the divided pn junctions. The depletion layer is thus apt to spread easily near the Schottky junction plane, and the withstand voltage can be obtained.

As an optional aspect, in the above-mentioned diode, an n type highly concentrated semiconductor region and a rear face electrode may be contained. The n type highly concentrated semiconductor region may be arranged to adjoin a rear face of the n type semiconductor region. The n type highly concentrated semiconductor region is to include a high impurity concentration thicker than the n type semiconductor region. The rear face electrode may be electrically connected to the rear face of the n type highly concentrated semiconductor region. The insulating region may be extended from the front face of the semiconductor substrate to reach the n type highly concentrated semiconductor region.

As an optional aspect, the front face electrode may include a first front face electrode and a second front face electrode. The front face electrode forms a Schottky junction on a part of the front face of the n type semiconductor region. The second front face electrode forms an ohmic junction with the p type semiconductor region. Herein, an ohmic junction signifies a junction in which a Schottky barrier does not exist substantially. There is substantially no difference in the ohmic junction between the barrier height of the semiconductor and the barrier height of the metal. When an outer voltage of the forward direction is applied to the ohmic junction, the electric current flows in proportion to the outer voltage according to Ohm's law. According to the above configuration, a potential difference does not arise approximately between the second front face electrode and the p type semiconductor region. This can enlarge more the potential difference of the pn junction formed by the p type semiconductor region and the n type semiconductor region while allowing such a pn junction formed by the p type semiconductor region and n type semiconductor region to function as a diode in the range of the relatively low forward voltage.

(Effect)

The above aspect of the disclosure can provide, in a diode having a p type semiconductor region in a part of a front face of an n type semiconductor region, a technology which utilizes the internal pn junction as an effective diode while reducing a forward resistance.

It will be obvious to those skilled in the art that various changes may be made in the above-described embodiments of the present invention. However, the scope of the present invention should be determined by the following claims.

What is claimed is:

1. A diode comprising:
an n type semiconductor region;
a p type semiconductor region provided in a part of a front face of the n type semiconductor region;
an anode electrode which adjoins a front face of the n type semiconductor region and a front face of the p type semiconductor region while at least forming a Schottky junction with a front face of the n type semiconductor region; and
an insulating region which has a first side and a second side adjacent to the n type semiconductor region,
the first side facing the second n type semiconductor region which is located below the Schottky junction,
the second side facing the n type semiconductor region which is located below a pn junction between the n type semiconductor region and the p type semiconductor region.

2. The diode according to claim 1, wherein
the insulating region is arranged, in a top view, along a border portion between a coverage where the Schottky junction exists and a coverage where the pn junction exists.

3. The diode according to claim 1, wherein:
the n type semiconductor region and the p type semiconductor region are provided in a semiconductor substrate;
the front face electrode is provided above the semiconductor substrate; and
the n type semiconductor region and the p type semiconductor region are arranged, in a top view, to alternate at least in one direction on a surface layer portion of the semiconductor substrate.

4. The diode according to claim 3, wherein
the insulating region is extended from a front face of the semiconductor substrate to a position deeper than the p type semiconductor region.

5. The diode according to claim 4, wherein
the insulating region penetrates the p type semiconductor region.

6. The diode according to claim 3, further comprising:
an n type highly concentrated semiconductor region which is provided to adjoin a rear face of the n type semiconductor region while having an impurity concentration higher than the n type semiconductor region does; and
a rear face electrode electrically connected to a rear face of the n type highly concentrated semiconductor region, wherein
the insulating region is extended from the front face of the semiconductor substrate to reach the n type highly concentrated semiconductor region.

7. The diode according to claim 1, wherein:
the front face electrode includes a first front face electrode and a second front face electrode;
the first front face electrode forming a Schottky junction with the n type semiconductor region; and
the second front face electrode forming an ohmic junction with the p type semiconductor region.
